(19) United States
(12) Patent Application Publication
(10) Pub. No.: US 2005/0269200 A1
(43) Pub. Date: Dec. 8, 2005

(54) Film deposition

(76) Inventors: Stephen Robert Burgess, Gwent (GB); Paul Rich, Gloucestershire (GB); James O'Sullivan, Cardiff (GB)

Correspondence Address: VOLENTINE FRANCOS, & WHITT PLLC, ONE FREEDOM SQUARE, 11951 FREEDOM DRIVE SUITE 1260, RESTON, VA, 20190, US

(21) Appl. No.: 11/137,430

(22) Filed: May 26, 2005

Related U.S. Application Data
(60) Provisional application No. 60/582,536, filed on Jun. 25, 2004.

(30) Foreign Application Priority Data
Jun. 4, 2004 (GB) 0412469.9

(51) Int. Cl. C23C 14/32

(52) U.S. Cl. 204/192.12; 204/298.2

(57) ABSTRACT

Films are deposited on a substrate using a plasma chamber having a target disposed about an axis and a magnetron rotatable about the axis at an adjustable offset from the axis to vary the pattern of ions impinging on the target. In the deposition of the films, a first film of target material is deposited with the magnetron at a first inner-offset position relative to the axis, and in the same chamber, a second film is deposited using a reactive physical vapour deposition process with the magnetron at a second outer offset position. The deposition of the first and second film can occur in any order.

### CROSS REFERENCED TO RELATED APPLICATION

A claim to priority is made to U.S. Provisional Application Ser. No. 60/582,536, filed Jun. 25^{th} 2004 and to British Patent Application No. 0412469.9, filed Jun. 4^{th} 2004.

### BACKGROUND OF THE INVENTION

1. Field of the Invention

This invention relates to methods of depositing films on the substrate using a plasma chamber having a target disposed about an axis and a magnetron rotatable about the axis at an adjustable offset from the axis.

2. Description of the Related Art

The use of magnetrons in sputtering processes is well known and the are provided for the purposes of controlling the erosion of the target. Examples of prior art systems are shown in WO-A-02/47110 wherein adjustment of the offset position of the magnetic assembly of the magnetron in accordance with a process characteristic is known and EP-A-1094495 in which a magnetron can take up two distinct rotation diameters, the first being used in deposition and the second being used for cleaning the target between deposition steps.

In each case the magnetron position is intended to achieve uniformity of process during the life of the target.

It is also well known that both non-reactive and reactive sputter processes can be used to form films of different nature and a typical example is the deposition of Ti followed by TiN for use as a liner or barrier layer in semiconductor devices. However, currently, these processes are often performed in separate chambers, because during the reactive sputtering, Titanium Nitride can become deposited on the target. There are also conflicts between the magnetic field which is most desirable for non-reaction sputtering and that which might be appropriate for the reactive sputtering.

### SUMMARY OF THE INVENTION

The present invention consists in a method of depositing films on a substrate using a plasma chamber having a target disposed about an axis and a magnetron rotatable about the axis at an adjustable offset from the axis to vary the pattern of ions impinging on the target the method including in either order;
(a) depositing a first film of target material with the magnetron at a first inner offset position relative to the axis, and
(b) depositing, in the same chamber a second film using a reactive physical vapour deposition process with the magnetron at a second outer offset position.

The second film may be deposited first in some embodiments for example for a barrier layer for use with copper. TaN would be deposited and Ta would then be deposited on top to receive the Cu layer.

The first offset position, is selected in order to minimise electron loss between the anode used to create the plasma and the chamber wall. It has been found that this means you need a magnetron arrangement that does not erode from the very edge of the target. However, with such a target/magnetron combination it has been discovered that problems arise particularly for reactive sputtering, because the target does not have a full face erosion and can become a particle source. This is due to deposition material re-depositing on the non-eroded region of the target. Where the material is the same as the target material (i.e. non-reactive deposition) the adhesion is generally quite good, but where, as in reactive sputtering, different material is deposited and this can readily delaminate, particularly due to the extremes and rapidity of the temperature cycling which occurs as the target bias is turned on or off.

Accordingly if this re-deposited material is not cleaned quickly it becomes a particle source.

By utilising the different offset positions for the reactive and non-reactive sputtering, the Applicants have managed to overcome this problem and enabled the two processes to be performed sequentially in a single chamber, which results in significant savings both in processing time and capital cost.

The outer offset deposition position is selected to limit or prevent build up of the second film material on an outer peripheral part of the target. This position may be adjusted in accordance with target usage. The Applicants have determined that in general it is desirable to move the offset position outwardly from the axis as the target becomes more eroded.

In a particular preferred embodiment the target material is Titanium and the second film is Titanium Nitride.

From a second aspect the invention consists in apparatus for depositing films on a substrate including a plasma chamber having a target disposed about an axis, a magnetron rotatable about the axis, a control device or means for adjusting the position of the magnetron between an inner offset position relative to the axis and an outer offset position and for running respective distinct deposition processes when the magnetron is in its inner and outer positions.

The control device or means may adjust the second offset position in accordance with target life.

### BRIEF DESCRIPTION OF THE DRAWINGS

Although the invention has been performed in various ways specific embodiments will now be described, by way of example with reference to the accompanying drawings, in which:

FIG. 1 is a schematic view of a plasma chamber for performing sputter deposition;

FIGS. 2(a) and (b) are schematic views of an existing arrangement. In 2(a) the magnetron is in its operative process position, whilst in 2(b) it is in the cleaning (non-process) position when there is no wafer and the wafer location is covered by a shutter.

FIG. 3 illustrates the increase in particles over a particular size when in a standard process there is no enhanced target edge cleaning;

FIG. 4 is a similar graph illustrating the improvement produced by enhanced target edge cleaning;

FIG. 5 illustrates target voltage as a function of the magnet position; and

FIG. 6 is a graph showing the level of base coverage in a 3:1 aspect ratio feature as a function of the offset.

### DETAILED DESCRIPTION OF THE PREFERRED EMBODIMENTS

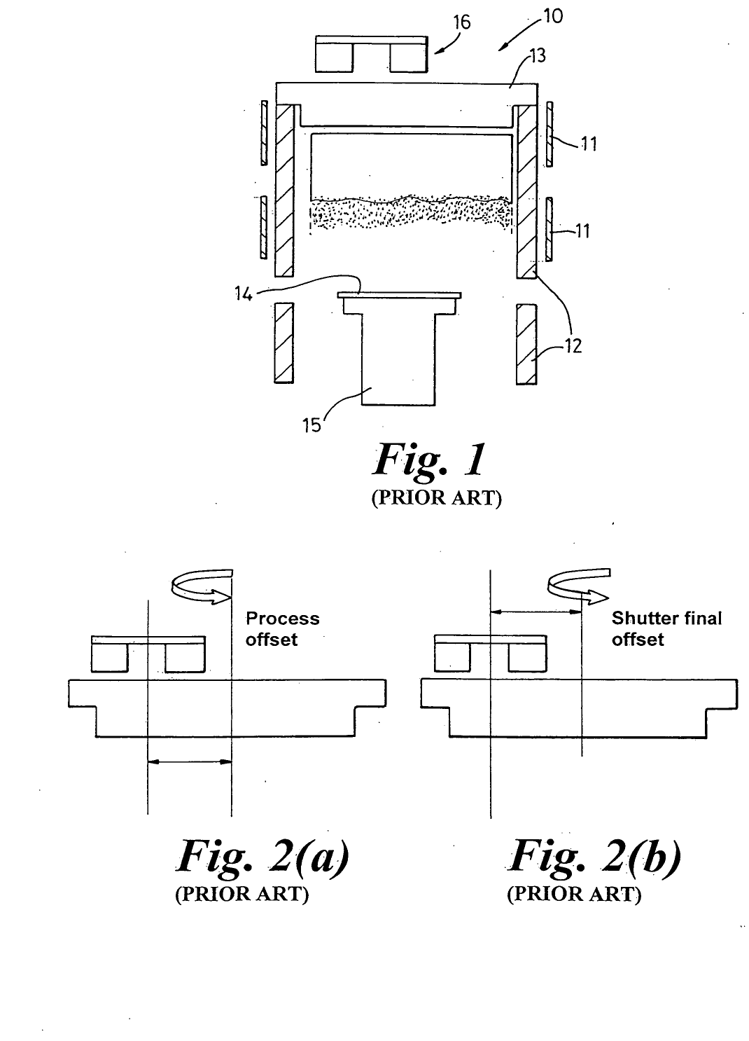

Thus in the standard Trikon Advanced Hi-Fill® AHF chamber, illustrated in FIG. 1 and generally indicated at 10, DC coils 11 extend down the chamber sidewalls 12 to allow the plasma to extend and fill a large volume of the chamber 10. This in turn increases the probability of the material leaving the target 13 becoming ionised before it reaches a wafer 14 located on a support 15. In order for this system to work correctly it is necessary to minimize any electron loss to the anode ring (not shown) and chamber walls 12. This can be achieved if the magnetron arrangement 16 is positioned so that the target material does not erode from the very edge of the target 13.

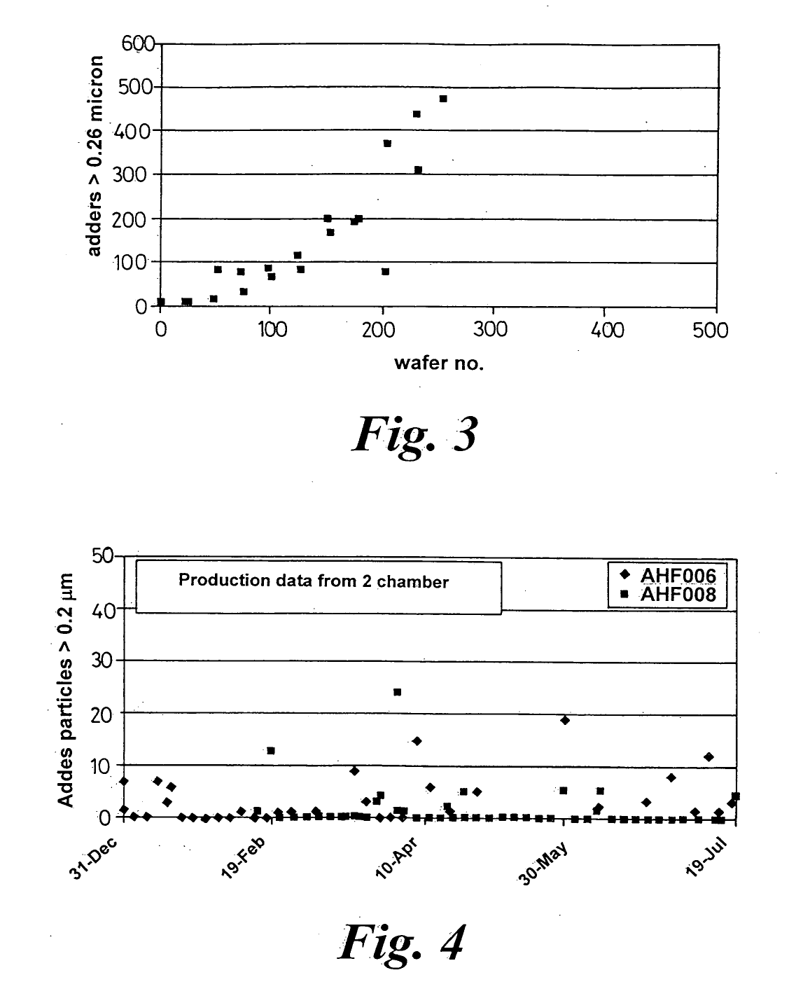

However, if one uses such a target 13 arrangement for reactive sputtering, because there is not full face erosion, the target 13 can become a particle source. As has been mentioned earlier the adhesion of the different material created in reactive sputtering can readily delaminate from the edge of the target and contaminate the substrate. This is demonstrated by the graph shown in FIG. 3. For this reason the Applicants proposed in WO02/47110 that in a reactive sputtering chamber, enhanced target edge cleaning should take place. This is typically performed after every wafer during the shutter step (that is when a shutter extends across the entry substrate support to protect it from deposition). The effect of this enhanced cleaning step is demonstrated at FIG. 4. The enhanced cleaning step involves turning off the DC coils 11, turning on the target 13 in a pure Ar ambient gas and moving the magnetron 16 towards the edge of the target.

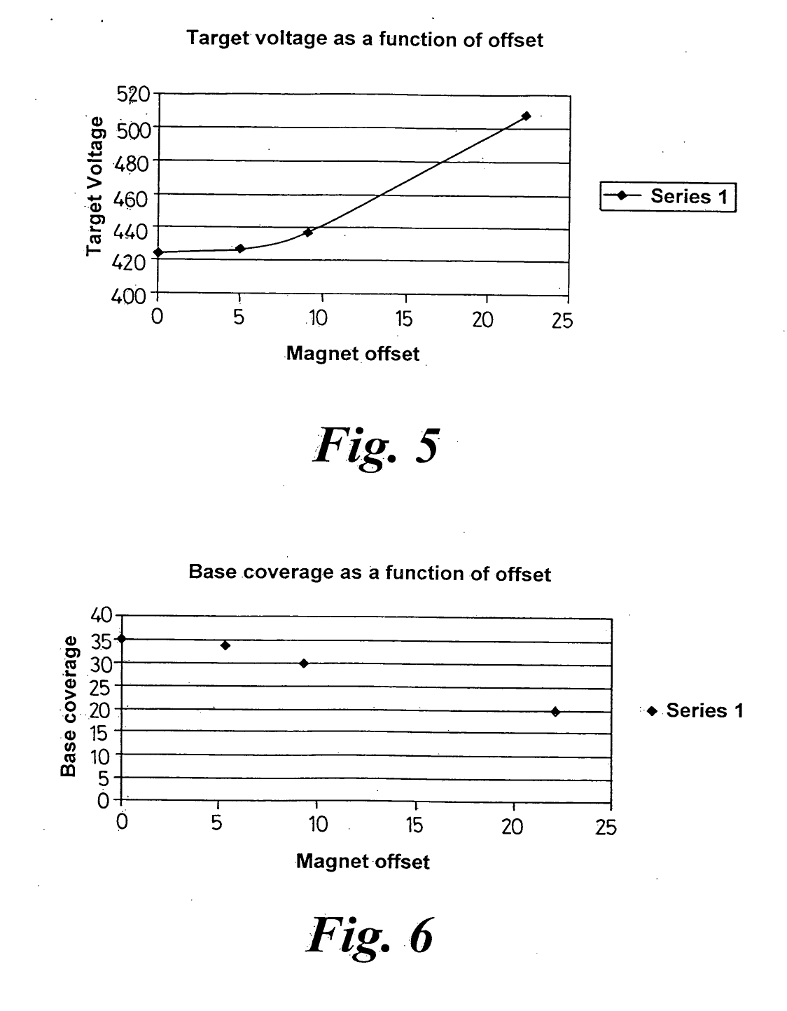

The Applicants have determined, as illustrated in FIG. 5, that there is a strong relationship between the position of the magnetron 16 (that is how close the magnets are to the target edge) and the degree of electron loss. This is plotted in FIG. 5. Lower target voltage is desirable as it indicates a more efficient system with less electron loss and such an operation induces more self ionisation. Increasing the magnetic offset results in the magnetron moving towards the edge of the target and the target voltage increases significantly as the magnetron moves out. This is the result of the losses to the anode and chamber walls. Similarly, as one might anticipate, the base coverage of a high aspect ratio feature decreases as the magnets move out (see FIG. 6).

The Ti sequence requires the maximum possible amount of ionisation to achieve maximum base coverage. For this it is necessary to minimize electron loss to the anode and chamber walls. In this case the magnetron 16 needs to move towards the centre of the target 13. In this mode of operation significant amounts of re-deposition at the target edge can be tolerated since this re-deposited material is the same as the target material. In this particular case the magnetron would be operated at an offset position close to the nominal zero for optimum performance.

In contrast the TiN deposition sequence, the Applicants can sometimes accept a reduction in the amount of ionisation, and therefore carefully control the position of the magnetron 16 in a compromise position. In such cases the magnetron 16 is moved towards the edge of the target 13. For example 15 mm offset may be chosen. This exact position of offset will depend precisely on application but will always be larger than the position used for the Ti deposition. A particular position is chosen such that the electron loss is controlled to an acceptable level (so as to achieve acceptable coverage) but at the same time the build up of un-desirable TiN deposition at the edge of the target is reduced. This will minimise the cleaning time of the target, typically at an offset of −25 mm, which is performed without the wafer in the chamber. This cleaning, as illustrated in FIG. 2(b) obviously wastes time and target material.

As the target erodes it has been found that the width of the TiN re-deposition zone at the edge of the target increases for a given TiN deposition step (results in longer cleaning steps being required). The probable cause of this is the plasma becoming more confined within the major erosion zones. For this reason the optimised offset position for TiN deposition will not remain the same during target operation. Hence as the target erodes this optimised TiN offset position will change and will very gradually move outwards. The Applicants propose to automatically adjust this using a specially written software sequence. This optimum position could be determined by a simple look up table that defines the correct offset for the TiN deposition step at a given target life or a more complex in-situ measurement and calculation performed automatically by the tool. It would be possible to write a sequence that automatically measures the target voltage as a function of offset. The optimum offset position could then be automatically calculated and adjusted from this data (for example you adjust the offset to operate at the knee of the voltage change as shown in FIG. 5).

1. A method of depositing films on a substrate using a plasma chamber having a target disposed about an axis and a magnetron rotatable about the axis at an adjustable offset from the axis to vary the pattern of ions impinging on the target, the method including in either order:
(a) depositing a first film of target material with the magnetron at a first inner offset position relative to the axis; and
(b) depositing in the same chamber, a second film using a reactive physical vapour deposition process with the magnetron at a second outer offset position.

2. A method as claimed in claim 1 wherein the second film is deposited first and the first film second.

3. A method as claimed in claim 1 including depositing a stack of alternate first and second films.

4. A method as claimed in claim 2 including depositing a stack of alternate first and second films.

5. A method as claimed in claim 1 wherein the outer offset deposition position is selected to limit or prevent build up of the second film material on an outer peripheral part of the target.

6. A method as claimed in claim 1 wherein the second outer offset position is adjusted in accordance with target usage.

7. A method as claimed in claim 1 wherein the target material is Titanium and the second film is Titanium Nitride and the first film is deposited first.

8. A method as claimed in claim 1 wherein the outer offset deposition position is selected to limit or prevent build up of the second film and the second outer offset position is adjusted in accordance with target usage.

9. Apparatus for depositing films on a substrate including a plasma chamber having a target disposed about an axis, a magnetron rotatable about the axis, a control device or means for adjusting the position of the magnetron between an inner offset position relative to the axis and an outer offset position and for running respective distinct deposition processes when the magnetron is in its inner and outer positions.

10. Apparatus as claimed in claim 9 wherein the control device or means adjusts the second offset position in accordance with target life.
